(19) United States
(12) Patent Application Publication
(10) Pub. No.: US 2009/0223551 A1
(43) Pub. Date: Sep. 10, 2009

(54) Process for making solar cells

(75) Inventors: Damoder Reddy, Los Gatos, CA (US); Craig Leidholm, San Jose, CA (US)

Correspondence Address: NOLD INTELLECTUAL PROPERTY LAW, 101 California Street, Suite 2450, San Francisco, CA, 94111, US

(73) Assignee: Solexant Corp., San Jose, CA (US)

(21) Appl. No.: 12/380,638

(22) Filed: Mar. 2, 2009

Related U.S. Application Data
(60) Provisional application No. 61/068,020, filed on Mar. 4, 2008.

(51) Int. Cl. H01L 31/042; H01L 31/0232; C23C 16/00; C23C 16/56

(52) U.S. Cl. 136/244; 438/69; 118/722; 118/724; 257/E31.127

(57) ABSTRACT

The invention describes a process and apparatus for making a photovoltaic device in a continuous roll to roll process. The fabrication apparatus in accordance with the present invention is quite novel and non-obvious and provides capital efficiency and advantages in processing for thin film solar cells.

### CROSS REFERENCE TO RELATED APPLICATIONS

This application claims priority to U.S. Provisional Patent Application 61/068,020 filed Mar. 4, 2008, the contents of which are incorporated herein by reference.

### BACKGROUND OF THE INVENTION

Increasing oil prices have heightened the importance of developing cost effective renewable energy. Significant efforts are underway around the world to develop cost effective solar cells to harvest solar energy. Currently, in order for solar cells to be cost effective with traditional sources of energy solar cells must be manufactured at a cost well below $1/watt.

Current solar energy technologies can be broadly categorized as crystalline silicon and thin film technologies. Approximately 90% of the solar cells are made from silicon—single crystal silicon or polycrystalline silicon. Crystalline silicon (c-Si) has been used as the light-absorbing semiconductor in most solar cells, even though it is a relatively poor absorber of light and requires a considerable thickness (several hundred microns) of material. Nevertheless, it has proved convenient because it yields stable solar modules with good efficiencies (13-18%, half to two-thirds of the theoretical maximum) and uses process technology developed from the knowledge base of the microelectronics industry. Silicon solar cells are very expensive with manufacturing cost above $3.50/watt. Manufacturing is mature and not amenable for cost reduction.

Second generation solar cell technology is based on thin films. Main thin film technologies are amorphous Silicon, Copper Indium Gallium Selenide (CIGS), and Cadmium Telluride (CdTe). Thin film solar cells made from Copper Indium Gallium Diselenide (CIGS) absorbers show promise in achieving high conversion efficiencies of 10-12%. The record high efficiency of CIGS solar cells (19.9% NREL) is by far the highest compared with those achieved by other thin film technologies. These record breaking small area devices have been fabricated using vacuum evaporation techniques which are capital intensive and quite costly. A number of companies (Honda, Showa Shell, Wurth Solar, Nanosolar, Miasole etc.) are developing CIGS solar cells on glass substrates and flexible substrates. However, it is very challenging to fabricate CIGS thin films of uniform composition on large area substrates. This is due partially to the deposition chemistry and necessity of subsequent reaction chemistry to form CIGS. This limitation also affects the process yield, which are generally quite low. Because of these limitations, implementation of evaporation techniques has not been successful for large-scale, low-cost commercial production of CIGS solar cells. CdTe does not suffer from those limitations and may be formed I a single step process.

CdTe solar cells with 16.5% efficiency have been demonstrated by the National Renewable Energy Laboratory (NREL). CdTe solar cells are sometimes made by depositing CdTe on 3 mm thick glass substrates and encapsulated with a second 3 mm cover glass. It is a slow and costly manufacturing process. Further, these CdTe solar cells are also very heavy and cannot be used for residential rooftop applications—one of the largest market segments of solar industry. There exists a need for an efficient manufacturing process for flexible CdTe solar cells.

### SUMMARY OF THE INVENTION

In one embodiment there is disclosed a process for manufacturing a photovoltaic device, comprising providing a substrate comprising a length of flexible foil, forming a set of multiple layers comprising a photovoltaic device on a section of the substrate, wherein at least one of said multiple layers comprises an absorber layer which comprises at least one Group II-VI, Group I-III-VI and Group IV compound. In one embodiment the set of multiple layers comprises an electrode layer, an absorber layer, a window layer and a TCO layer. In one embodiment the substrate may be transparent or alternatively it may be made of a metal and be opaque. In one embodiment the flexible foil continuously moves past at least one deposition source capable of forming a layer using at least one coating drum having the capability of being heated or cooled. In one embodiment the substrate continuously moves in a free span configuration past at least one deposition source capable of forming a layer. Drums and free span movement may be combined. The length of flexible foil may have a first side and a second side opposite from the first side, and the forming of a set of multiple layers includes forming at least one layer on the first side and the second side. In one embodiment of the present invention the electrode layer, the absorber layer, the window layer and the TCO layer may be formed at substantially the same time while continuously moving the substrate past at least one deposition source capable of forming a layer or in another embodiment the electrode layer is formed on the substrate, the absorber layer is formed after the electrode layer, the window layer is formed after the absorber layer, and the TCO layer is formed after the absorber layer, while continuously moving the substrate past at least one deposition source capable of forming a layer. CIGS and the related materials such as CIS, CIGSe are examples of Group I-III-VI materials. Amorphous silicon, micro-crystalline silicon, micromorphous silicon and crystalline silicon are examples of Group IV materials. Also disclosed herein is an apparatus for making a photovoltaic device, comprising a supply chamber for supplying a substrate comprising a length of flexible foil, first, second and third chambers, wherein each chamber independently comprises at least one deposition source, and means for transporting the length of flexible foil past at least one deposition source, and means for controlling each deposition source. There may be at least one coating drum which is capable of being heated or cooled. Alternatively or additionally at least one of said first, second or third chambers comprises means for transporting the length of flexible foil past least one deposition source in a free span configuration. Further the flexible foil may comprise a first side and an opposite second side, and at least one chamber has at least one deposition source positioned on a first side and/or on a second side. The invention contemplates photovoltaic devices made by the above method and/or apparatus.

Advantageously, the deposited layers according to the process described herein do not get exposed to the ambient environment which can lead to oxidation or other contamination issues, which can reduce the solar cell performance and yield. Another advantage to the present invention is that the inside of the film-forming chamber is not exposed to atmospheric pressure resulting in a reduction of inner wall wetting by water vapor.

### BRIEF DESCRIPTION OF THE DRAWINGS

FIG. 1 shows a general schematic of a side view of one embodiment of the invention where a flexible foil is arranged in a roll to roll fashion, from supply roll to take-up roll.

FIG. 2 shows a general schematic of a side view of one embodiment of an apparatus for performing the process of the present invention.

FIG. 3 shows a general schematic of a side view of one embodiment of an apparatus for performing the process of the instant invention having a vacuum chamber with free-span chambers.

FIG. 4 shows a general schematic of a side view of one embodiment of an apparatus for performing the process of the instant invention with multiple free span chambers.

FIG. 5 shows a general schematic of a side view of one embodiment of the present invention having patterning systems located within the chambers.

FIG. 6 shows a general schematic of a side view of one embodiment of the present invention which allows for the possibility of processing foils without the use of a drum for temperature control.

### DETAILED DESCRIPTION OF THE EMBODIMENTS

This invention teaches a method of fabricating a thin film solar cell on a flexible substrate. The invention discloses the fabrication of a complete device whereby a bare flexible substrate is supplied and a complete solar cell device is realized in a continuous process.

Reference will now be made in detail to some specific embodiments of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In this specification and the appended claims, the singular forms “a,” “an,” and “the” include plural reference unless the context clearly dictates otherwise. Unless defined otherwise, all technical and scientific terms used herein have the same meaning as commonly understood to one of ordinary skill in the art to which this invention belongs.

By “flexible” it is meant capable of being bent. This invention contemplates that a wide range of materials are suitably flexible to serve as foils. Preferably the foil or substrate material is flexible enough to be wound on a roll with no deleterious effects.

By “foil” it is meant a sheet, woven or non-woven web, and/or a laminate or other structure suitable for a photovoltaic device substrate comprising any material suitable for use with a photovoltaic device in accordance with the present invention such as a metal (for example, Al, Mo, Cu), a metal alloy (for example, stainless steel), a polymer (for example, a polyimide, a polyamide, a polyethersulfone, a polyetherimide, a polyethylene naphthalate, a polyester, etc.) or mixtures and/or laminates thereof. The foil may be opaque or transparent. The foil may comprise any shape, thickness, width or length suitable for the process described herein. The foil may comprise leaders or “breaks” where the foil is spliced together with any suitable material and still comprise a continuous “length” in accordance with this invention. Optionally the foil may comprise a laminate of one or more materials preferably one comprises an electrically conductive material. The foil may have any number of holes placed therein by any process for a variety of uses. Preferably the flexible foil serves as the substrate of the photovoltaic device according to the process of the invention. The flexible foil may serve as an electrode or be made of a laminate comprising an electrode material in one layer. The foil may have a first side and an opposite second or back-side. When the foil is used as a substrate herein it must be about 25 microns to 500 microns, preferably about 150 microns to function as a substrate in most environments. By “roll to roll” it is meant that the process be fed with a roll of flexible foil and that the process comprise a take up roll around which is wound the completed flexible solar cell and is a preferred method to be used in conjunction with the present invention. The invention contemplates that the flexible foil may travel in both directions in the roll to roll configuration.

By “series of deposition sources capable of forming layers on the flexible foil” it is meant at least two “deposition sources” capable of depositing or otherwise creating layers or etching, scribing or otherwise acting on the flexible foil.

By “forming a layer” it is meant those steps for depositing, etching, reacting scribing or otherwise creating or adding to a layer, or acting on a layer already present.

“Depositing a layer” shall include those step or steps for forming, reacting, etching and/or scribing a layer which includes PVD, CVD, evaporation and sublimation.

“Deposition sources” as used herein is broadly meant to include those apparatus and materials capable of creating or forming the layers by, but not limited to, physical and chemical vapor deposition apparatus. Also, the invention contemplates that “deposition sources” and shall also include apparatus and materials for forming, reacting, etching and/or scribing or otherwise acting or performing chemical reactions on the layers of the photovoltaic device to create or alter a layer or layers.

By “free span” it is meant allowing processing of the foil without the use of a drum. In one embodiment of the present invention the foil is worked on by multiple deposition apparatus on the first and second sides of the foil, at the same time if so desired. “Free span” does not limit the entire process of the invention drum free, though that is an embodiment, but contemplates the use at least one drumless deposition processes. Three may be a drum process in a chamber with a free span configuration in some embodiments, or there may be no drums in any of the chamber(s). There is known in the art multi-rolls suitable for this purpose which may aid in the guiding and tensioning of the foil.

“Vacuum chamber” as used herein is meant to include a chamber having the ability of controlling the pressure through those means known in the art.

By “photovoltaic device” as used herein it is meant a multilayered structure having the least amount of layers necessary where in a working environment with proper leads and connections is capable of converting light into electricity. Preferably the device contains at least the following layers in order: a substrate/electrode layer/absorber layer/window layer and a TCO layer. In one embodiment the photovoltaic device has a superstrate configuration and the device has at least the following layers a in order: substrate/TCO/Window layer/absorber layer/electrode layer. In a superstrate configuration the substrate may be transparent or opaque. In a preferred embodiment the substrate comprises a metal and is opaque; In both configurations it is preferred that there is a barrier interface layer between the absorber layer and the electrode layer. The device may have any further structure necessary to practically utilize the device such as leads, connections, etc. The above preferred embodiments of the present invention do not limit the order of layers or deposition order of the photovoltaic device. When it is recited “forming a set of multiple layers comprising a first photovoltaic device” the invention is not limited to exactly the order of deposition of any particular set of layers or to the layer order on the substrate.

By “set of multiple layers” it is meant the minimum amount and of layers having the correct composition necessary that when properly placed in service is capable of acting as a solar device, i.e. converting light into electricity.

As used herein the word “continuous” means the formation of at least one set of multiple layers onto a length of flexible foil in a process where a foil is passed past a set of deposition sources for forming the layers in a process where the running length of flexible foil that serves as a substrate extends continuously from an input source (supply roll) to a take up roll or other means for ending the process, while passing a set of deposition sources. The invention also contemplates that “continuous” may mean the backwards or opposite travel of the flexible foil past a set of deposition sources. This embodiment is useful for a variety of purposes, including reprocessing.

“Means for transporting a flexible foil” as used herein includes take up and supply rolls to effectuate a roll to roll system, a roll to sheet system, or a free span configuration including multi-rolls in any number or shape or configuration or a system including any combination of the above. It also includes a drum as discussed herein. Any of the drum, supply roll, take up roll, multi-roll may be free rolling or mechanically driven and controlled by the system computer.

“Means for forming multiple layers on the flexible foil” includes physical and vapor deposition sources and apparatus, etching, scribing, patterning, cleaning and other such processes and apparatus as disclosed herein to affect a change, create or react any or all of the layers.

“Means for independently controlling each deposition source” includes those techniques in the art for controlling multiple deposition processes including but not required or limited to computers with the accompanying software.

In one embodiment of the present invention photovoltaic devices comprise a substrate layer/electrode layer/absorber layer/window layer/TCO layer, where TCO stands for transparent conductive oxide. It is preferred that there is a barrier interface layer between the electrode and absorber layer resulting in a structure: substrate layer/electrode layer/barrier interface layer/absorber layer/window layer/TCO layer. In one embodiment the electrode (conductor) is typically a metal (Al, Mo, Ni, Ti, etc.) but can be a semiconductor such as ZnTe. The metal electrode has a thickness of about 200 nm to 2,000 nm, preferably about 500 nm. Interface (barrier) layer materials are known in the art and any suitable material such as ZnTe or similar materials that provide advantages in contacting absorber materials such as CdTe and/or CIGS which do not easily form ohmic contacts directly with metals. The electrode metals are typically deposited by sputtering. Planar or rotatable magnetrons may be used. The interface layer can be deposited by a similar method or by evaporation. In one embodiment of the present invention sputtering these two layers can be accomplished in a single chamber, with the substrate either on a temperature-controlled drum or in free-span. This will provide unexpected advantages for the substrate handling and heat load.

In one embodiment of the present invention after the electrode and interface layer are deposited, the flexible foil travels through another chamber. Differentially pumped slits for environment isolation between chambers may be used.

In one embodiment the absorber layer can be deposited by sputtering or other physical vapor deposition (PVD) methods known in the art for this purpose, such as close space sublimation (CSS), vapor transport deposition (VTD), evaporation, close-space vapor transport (CSVT) or similar PVD method or by chemical vapor deposition (CVD) methods. The absorber layer may comprise compounds selected from the group consisting of Group II-VI, Group I-III-VI and Group IV compounds. Group II-VI compounds include ZnS, ZnSe, ZnTe, CdS, CdSe, CdTe, HgS, HgSe, HgTe, MgTe and the like. Preferred are Group II-VI compounds and particularly preferred is CdTe.

In one embodiment the absorber material can be deposited while controlling the substrate, typically at temperatures above 400° C. CdTe and CIGS are preferred absorbers. CIGS is CuInₓGa₁₋ₓSe, where 0≦x<1. Included herein includes the family of materials generally referred as CIGS include CIS, CISe, CIGSe, CIGSSe. The CdTe absorber layer thickness is about 1 micron to 10 microns, preferably about 5 microns. The CIGS absorber thickness is about 0.5 microns to 5 microns, preferably 2 microns.

Following deposition of the absorber layer, a window layer can be deposited by similar PVD methods. Window layer(s) may comprise CdS, ZnS, CdZnS, ZnSe and/or In₂S₃. In a preferred embodiment CdS is the window layer material and may be deposited by those techniques known in the art such as CSS or VTD. The CdS window layer thickness is about 50 nm to 200 nm, preferably about 100 nm. Subsequent to the window layer deposition a post-process grain growth step is contemplated, such as a CdCl₂ treatment which is known in the art for CdTe grain growth. This can be either before or after CdS deposition and in some embodiments occur in the same deposition chamber as the absorber or could occur in a third, isolated chamber.

In one embodiment following the absorber and window layer deposition and absorber post-deposition grain growth step, the TCO can be deposited by PVD methods, for example sputtering. Common TCO's known in the art for this purpose include ZnO, ZnO:Al, ITO, SnO₂ and CdSnO₄. ITO is In₂O₃ containing 10% of Sn. The TCO thickness is about 200 nm to 2,000 nm, preferably about 500 nm.

The invention contemplates the deposition of additional layers if desired. Non-limiting examples include a top metal contact in a grid-like pattern for improved solar cell device performance.

Once completed, the flexible solar cell can be re-rolled onto a take-up spool. This method is either semi-continuous or continuous depending on whether a new flexible foil leader is spliced into the previous flexible foil tail to maintain a continuous flexible foil. In one embodiment the flexible foil may be initially threaded through the system, run through the processes and then dismounted. This means opening the system each time a flexible foil is to be started in order to thread the flexible foil through the system. With periodic maintenance being required on such a system the length of flexible foil may be synchronized with the maintenance schedule such that this does not impact system up time and process throughput.

Photovoltaic devices made in accordance with the present invention have the unexpected advantage of having good layer cohesion over the length of the substrate which may be 500 meters long. In addition the layers show an unexpected consistent stoichiometric composition.

In one embodiment the cells can be integrated in situ into a module in a monolithic integration scheme. This contemplates the use of laser and/or mechanical scribing tools internal to the system. The invention contemplates that the location of scribing processes can be variable within the system. In one embodiment the first scribe may be positioned after the back electrode and the barrier interface layer have been deposited, immediately prior to the absorber deposition. In another embodiment the invention contemplates locating the second scribe directly after the high-resistivity ZnO layer, just prior to the ZnO:Al or low-resistivity TCO layer deposition. The third and final scribe may, in one embodiment be placed after the low-resistivity TCO but, as this is the final layer in some embodiments, could be done outside the fabrication system on a separate stand-alone system, or perhaps in-line with subsequent process tools such as slitting/sheeting, contacting or packaging. Scribes may be placed in front of and in back of the substrate.

In one embodiment treatment or annealing in a reducing atmosphere such as H₂ or forming gas is contemplated. Alternatively treatment or annealing in an oxidizing atmosphere such as O₂ containing, HCl containing, nitric oxide containing atmospheres is also contemplated with in the process of the instant invention.

In one embodiment of the present invention the fabrication system provides for no front-side touching of the substrate. In a preferred embodiment all layers are deposited by PVD methods including sputtering, evaporation, close-space sublimation, closed space vapor transport, vapor transport deposition or other such methods.

The invention will now be described with reference to particular embodiments referring to the Figures.

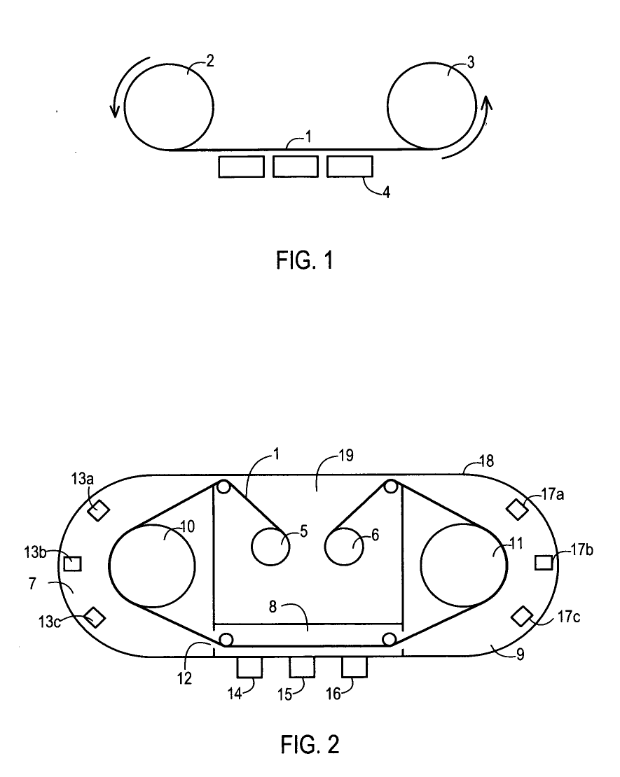

FIG. 1 shows a general schematic according to one embodiment of the present invention. A flexible foil 1 is arranged in a roll to roll fashion from supply roll 2 to take-up roll 3. Between supply roll 2 and take-up roll 3 is a deposition zone or material source zone wherein evaporation-type deposition sources 4, including traditional evaporation, close-space sublimation, vapor transport, close-space vapor transport and chemical vapor are located. In this deposition zone the layers of a thin-film solar cell, such as CdTe, are deposited by physical vapor or chemical vapor deposition means onto the passing flexible foil in a continuous manner. The invention contemplates that deposition may occur while the foil is moving past the sources at any a speed suitable to adequately form the required layer in size and composition.

Alternatively, the deposition process may include a step where the foil is temporarily stationary inside the chamber, said stationary step programmed to affect a particular process enacted upon the foil. The flexible foil may be maintained at any tension suitable to accomplish the particular deposition or scribing, etc. process in that particular chamber. The speed may not be steady state, but may vary depending on the process. It is understood that the invention is not limited to a roll-to-roll for supply and take up of the foil. For example the take up roll may be substituted for another means, such as a cut and stack apparatus. Similarly the supply roll may be substituted with other means.

FIG. 2 shows another embodiment of the apparatus 18 of present invention. In this embodiment a flexible foil 1 is arranged in a roll to roll fashion in a vacuum supply chamber 19 and moved through the chamber from supply roll 5 to take-up roll 6 both located in an isolated chamber 19 from other processing/deposition chambers 7, 8 and 9. Each of processing/deposition chambers 7 and 9 can have drums 10 and 11 around which the foil is threaded to allow for control of the substrate temperature by control of the drum temperature, either chilled or heated. Chamber 7 can be a PVD deposition chamber where each of 13a, 13b and/or 13c may independently comprise sputtering cathodes/target set and are configured to deposit an electrode onto the flexible foil and a barrier interface layer onto the electrode. The invention contemplates that plural thin metal electrode layers may be deposited as an electrode.

In one embodiment, the drums contemplated for use in the instant invention are typical coating drums having a double wall gap (not shown) for passage of a cooling or heating gas or liquid. Each chamber has, where required, means such as valves for flowing source materials into the chamber such as reactive sputtering gasses or Ar. Electric heating of the drums is also contemplated. In one embodiment a sub-chamber 8 can be used between chambers 7 and 9 for additional processing (such as, but not limited to, heating, cooling, deposition, etching, and cleaning) of the foil in a free-span mode. The free-span chamber may serve as a deposition chamber for depositing on the front and rear of the foil, or depositing on one side and etching, scribing, etc. on the rear side. Chamber environments according to the instant invention can be isolated where necessary (i.e. to avoid contamination) by the use of small regions 12, i.e. slits, around the foil which have differential pumping specifically for chamber isolation purposes. Each deposition chamber is effectively isolated from each other so cross-contamination cannot occur.

FIG. 2 depicts three deposition sources but the invention is not so limited. One, two, three, four, five, or more may be used if desired. The invention is also not limited to the exact physical location of the sources. The foil will pass through differentially pumped slit 12 into chamber 8. The absorber layer deposition can be done by PVD sources 14 such as CSS, VTD or evaporation. The invention contemplates selenization processes known in the art to improve uniformity, stoichiometry, and morphology of CdTe and CIGS thin films. It is understood that although as shown in FIG. 2, 14 is outside the chamber, it is considered by the invention that the chamber comprises the PVD sources indicated by 14. Following absorber deposition the CdS and post-deposition grain growth treatment, typically in CdCl₂, can occur. The CdS layer may be annealed at 450° C. for recrystallization and activation of the CdTe/CdS heterojunction by depositing CdCl₂ on CdTe and annealing. These two processes may be interchanged in priority and are shown in FIG. 2 as 15 and 16. In one embodiment a final step in the process is the formation of a TCO which can be deposited in chamber 9 by PVD methods such as sputtering. FIG. 2 shows cathodes 17a, 17b and 17c used for the deposition of these layers. FIG. 2 shows 4 chambers. It is understood that the present invention may include less or more chambers depending on the desired deposition steps. The invention contemplates backside deposition techniques for use in any free span chamber of the present invention, for example chamber 8 (backside deposition source not shown).

Referring to FIG. 2 the invention contemplates that in one embodiment an electrode of Al is sputtered by PVD using source 13a. Then a barrier interface layer of ZnTe is deposited on the Al using source 13b. The foil may be stationary or moving at a pace suitable to accomplish deposition. The foil passes through slit 12 and in the next step an absorber layer of CdTe is deposited onto the barrier interface layer. Substantially at the same time in chamber 7 an electrode layer and barrier interface layer are being deposited on another piece of the flexible foil. The portion of the flexible foil 1 having deposited thereon the electrode (Al)/barrier interface layer (ZnTe)/absorber (CdTe) may be scribed, etched, etc. by the sources/apparatus of 15 and 16 to divide and serially connect adjacent areas. For example, a window layer of CdS may be deposited and the set of multiple layers may be scribed, with a second scribing of CdS and CdTe layers to create a via, ink deposition and curing according to techniques known in the art.

If desired layer growth may be monitored by a few techniques known in the art, based on changes of emissivity from the growing surface, and in-situ monitoring of composition using X-ray fluorescence.

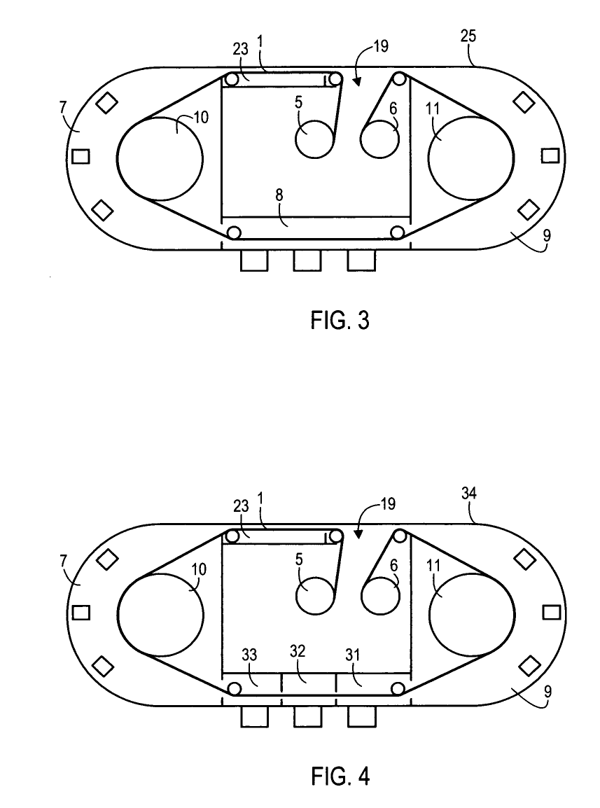

FIG. 3 shows another embodiment of the apparatus 25 of the present invention. The invention contemplates free-span chambers 23 and 8 located on the top and bottom of chamber 19. A flexible foil 1 arranged in a roll to roll fashion in a vacuum chamber 19, a supply roll 5, a take-up roll 6 and other processing/deposition chambers 7, 8 and 9. Deposition chambers 7 and 9 show drums 10 and 11. Free span chamber 23 allows for the pre treatment of the flexible foil if desired or for a chamber for deposition of an electrode.

FIG. 4 shows another embodiment of the apparatus 34 of the present invention. In FIG. 4 there are three lower free-span separate chambers 31, 32 and 33. The invention contemplates that additional processing with different environmental requirements such as pressure or gas composition to be processed sequentially without cross interference. It is understood that the number of separate free chambers is a design choice depending on engineering requirements and thee may be one, two, three or more. Each free-span chamber may have the necessary valves for input and output of gasses, source materials, waste products, etc. Each chamber is separated by differential pumped slits as described above. A flexible foil 1 arranged in a roll to roll fashion in a vacuum chamber 19, a supply roll 5, a take-up roll 6 and other processing/deposition chambers 7, 8 and 9. Deposition chambers 7 and 9 show drums 10 and 11. Free span chamber 23 allows for the pre treatment of the flexible foil if desired or for a chamber for deposition of an electrode.

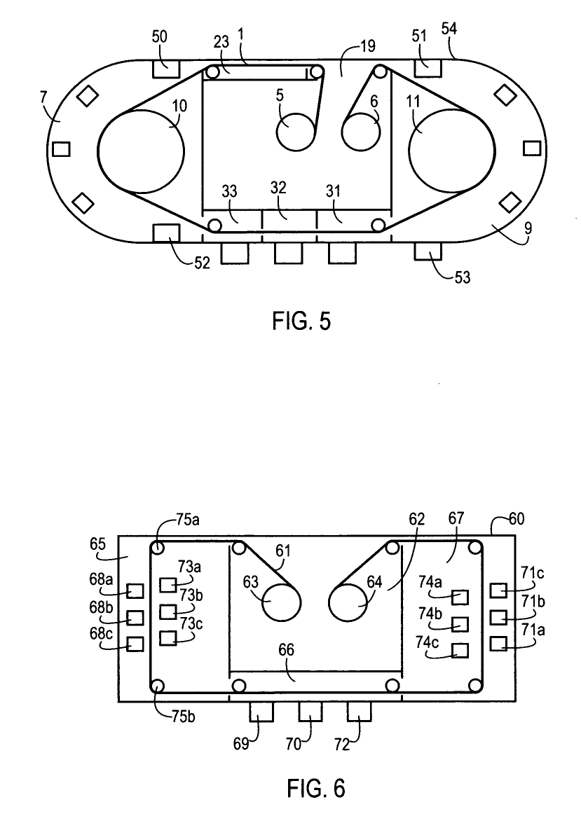

FIG. 5 shows another embodiment of apparatus 54 of the present invention. The invention contemplates that patterning systems may be located within or outside the chambers. FIG. 5 shows patterning systems 50, 51, 52 and 53 located within or outside the chambers. It is understood that any number of patterning systems may be utilized depending on the desired product. These patterning systems would allow for patterning such as scribing required in solar cell interconnect designs such as monolithic integration. A flexible foil 1 arranged in a roll to roll fashion in a vacuum chamber 19, a supply roll 5, a take-up roll 6 and other processing/deposition chambers 7, 8 and 9. Deposition chambers 7 and 9 show drums 10 and 11. Free span chamber 23 allows for the pre-treatment of the flexible foil if desired or for a chamber for deposition of an electrode.

FIG. 6 shows another embodiment of the present invention. FIG. 6 shows a processing apparatus 60 that processes a flexible foil 61 shown arranged in a roll to roll fashion in a vacuum chamber 62 and capable of being moved through the chamber 62 from supply roll 63 to take-up roll 64 both located in an isolated chamber 62 from other processing/deposition chambers 65, 66 and 67. In one embodiment each of the chambers 65, 66 and 67 can be free span, allowing processing of the foils without the use of a drum for temperature control. In this embodiment the foil may achieve higher temperatures than a drum configuration since the drum can be limited in temperature by the boiling point of the media inside the drum or by the thermal limitations of the drum such as the maximum drum bearing temperature. Additionally the free span configuration may provide additional degrees of freedom of the foil which is not linked to the drum by tension. Chamber 65 can be a PVD deposition chamber wherein sputtering cathodes/targets 68a, 68b and/or 68c can deposit the first barrier and conducting layers prior to absorber deposition. The absorber deposition can be done by PVD sources such as CSS, VTD or evaporation and are shown as 69 in this drawing. Following absorber deposition the process and apparatus provides for CdS and post-deposition grain growth treatment, typically in CdCl₂. These two processes may be interchanged in priority and are shown in 70 and 72. In one embodiment a final step in the process is the formation of a TCO which can be deposited in chamber 67 by PVD methods such as sputtering. Cathodes 71a, 71b and 71c are used for the deposition of these layers. The invention contemplates that in the free span mode deposition sources such as sputtering cathodes/targets 73a, 73b and 73c may be present to deposit layers on the back side of the flexible foil. Further non-limiting examples of back side deposition processes and apparatus are shown in 74a, 74b and 74c. Multi-rolls 75a and 75b are configured to guide the flexible foil. There may be any number of rolls in any configuration or shape desired to move the foil through the chamber and around and past deposition sources.

It is understood that the embodiments described herein disclose only illustrative but not exhaustive examples of the layered structures possible by the present invention. Intermediate and/or additional layers to those disclosed herein are also contemplated and within the scope of the present invention. Coating, sealing and other structural layers are contemplated where end use of the photovoltaic device warrants such construction.

All patents, publications and disclosures disclosed herein are hereby incorporated by reference in their entirety for all purposes.

What is claimed is:

1. A process for manufacturing a photovoltaic device, comprising:
providing a substrate comprising a length of flexible foil,
forming a set of multiple layers comprising a photovoltaic device on a section of the substrate, wherein
at least one of said multiple layers comprises an absorber layer, and
the absorber layer comprises at least one Group II-VI compound.

2. A process according to claim 1, wherein:
the set of multiple layers comprises an electrode layer, an absorber layer, a window layer and a TCO layer.

3. A process according to claim 1, wherein;
the substrate is transparent.

4. A process according to claim 1, wherein;
the substrate comprises a metal and is opaque.

5. A process according to claim 1, further comprising:
continuously moving the length of flexible foil past at least one deposition source capable of forming a layer, wherein
the foil is transported using at least one coating drum having the capability of being heated or cooled.

6. A process according to claim 1, further comprising:
continuously moving the length of flexible foil in a free span configuration past at least one deposition source capable of forming a layer.

7. A process according to claim 6, wherein:
the length of flexible foil has a first side and a second side opposite from the first side, and
the forming of a set of multiple layers includes forming at least one layer on the first side and the second side.

8. A process according to claim 1, wherein:
the electrode layer, the absorber layer, the window layer and the TCO layer are formed at substantially the same time,
while continuously moving the substrate past at least one deposition source capable of forming a layer

9. A process according to claim 1, wherein:
the electrode layer is formed on the substrate,
the absorber layer is formed after the electrode layer,
the window layer is formed after the absorber layer, and
the TCO layer is formed after the absorber layer,
while continuously moving the substrate past at least one deposition source capable of forming a layer.

10. A process according to claim 9, further comprising:
continuously moving the substrate past at least one deposition source capable of forming a layer, wherein
the foil is transported using at least one coating drum having the capability of being heated or cooled.

11. A process according to claim 9, wherein:
continuously moving the substrate in a free span configuration past at least one deposition source capable of forming a layer.

12. A process according to claim 1, further comprising:
at least one process independently selected from the group consisting of annealing, a CdCl₂ treatment, selenization, scribing, laser patterning and mechanical patterning.

13. A process according to claim 1, wherein:
the absorber layer comprises CdTe.

14. A photovoltaic device made by the method of claim 1.

15. A process for manufacturing a photovoltaic device, comprising:
providing a substrate comprising a length of flexible foil,
continuously moving the substrate in a free span configuration past at least one deposition source capable of forming a layer, and
forming a set of multiple layers comprising a photovoltaic device on a section of the substrate, wherein: the length of flexible foil has a first side and a second side opposite from the first side, and the forming of a set of multiple layers includes forming at least one layer on the first side and the second side.

16. A process according to claim 14, wherein
the set of multiple layers comprises an electrode layer, an absorber layer, a window layer and a TCO layer.

17. A process according to claim 16, wherein:
the absorber layer comprises a material selected from the group consisting of Group II-VI, Group I-III-VI and Group IV compounds.

18. A process according to claim 17, wherein:
the absorber layer comprises CdTe.

19. A process according to claim 17, wherein:
the absorber layer comprises CIGS.

20. A process according to claim 17, wherein:
the absorber layer comprises a material selected from the group consisting of amorphous silicon, microcrystalline silicon, micromorphous silicon, crystalline silicon and silicon germanium.

21. A process according to claim 15, wherein;
the substrate is transparent.

22. A process according to claim 15, wherein;
the substrate comprises a metal and is opaque.

23. A process according to claim 15, further comprising:
at least one process independently selected from the group consisting of annealing, a CdCl₂ treatment, selenization, scribing, laser patterning and mechanical patterning.

24. An apparatus for making a photovoltaic device, comprising:
a supply chamber for supplying a substrate comprising a length of flexible foil, first, second and third chambers, wherein
each chamber independently comprises at least one deposition source, and means for transporting the length of flexible foil past at least one deposition source, and
means for controlling each deposition source.

25. An apparatus for making a photovoltaic device according to claim 24, further comprising:
at least one coating drum which is capable of being heated or cooled.

26. An apparatus for making a photovoltaic device according to claim 24, further comprising:
at least one of said first, second or third chambers comprises means for transporting the length of flexible foil past least one deposition source in a free span configuration.

27. An apparatus for making a photovoltaic device according to claim 26, wherein:
the flexible foil has a first side and an opposite second side, and
at least one chamber has at least one deposition source positioned on a first side and/or on a second side.
